(19) United States
(12) Patent Application Publication
(10) Pub. No.: US 2009/0213550 A1
(43) Pub. Date: Aug. 27, 2009

(54) ELECTRONIC DEVICE

(75) Inventor: Takeshi Hongo, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/372,468

(22) Filed: Feb. 17, 2009

(30) Foreign Application Priority Data
Feb. 22, 2008 (JP) 2008-041870

(51) Int. Cl. H05K 7/20

(52) U.S. Cl. 361/704

(57) ABSTRACT

According to one embodiment, an electronic device comprises a circuit component, a heat sink configured to dissipate heat generated by the circuit component to the outside, and a first heat transfer sheet and a second heat transfer sheet that are arranged adjacent to each other between the circuit component and the heat sink and have thermal conductivity for thermally connecting the circuit component to the heat sink. The second heat transfer sheet has a rigidity greater than that of the first heat transfer sheet and is provided with through-holes. The first heat transfer sheet has a thermal conductivity and an elasticity greater than those of the second heat transfer sheet, and is pushed into the through-holes to thermally connect the circuit component to the heat sink.

### CROSS-REFERENCE TO RELATED APPLICATIONS

This application is based upon and claims the benefit of priority from Japanese Patent Application No. 2008-041870, filed Feb. 22, 2008, the entire contents of which are incorporated herein by reference.

### BACKGROUND

1. Field

One embodiment of the present invention relates to an electronic device comprising a cooling system for cooling the circuit components of the device.

2. Description of the Related Art

Jpn. Pat. Appln. KOKAI Publication No. 2004-22738 discloses an electromagnetic noise absorption sheet having a heat dissipation function. This electromagnetic noise absorption sheet is interposed between the circuit components and a heat sink. The sheet comprises electromagnetic noise absorption layers for blocking the electromagnetic noise conveyance, and a heat transfer layer interposed between the electromagnetic noise absorption layers. Each of the electromagnetic noise absorption layers has through-holes therein and a heat transfer material to fill the through-holes. The electromagnetic noise absorption layers have a low thermal conductivity, and therefore thermal conduction in this electromagnetic noise absorption sheet is carried out mainly by the heat transfer material in the through-holes. The heat transfer material is the same material as that of the heat transfer layer, or a different material from the layer.

The heat generated by the circuit components is conducted to the heat sink by way of the heat transfer material of the electromagnetic noise absorption layers and the heat transfer layer. The heat received by the heat sink is dissipated to the air. The electromagnetic noise absorption sheet solves a heat-related problem by improving the heat dissipation of the circuit components, and also suppresses the electromagnetic noise emission problem.

According to the conventional technology incorporating the electromagnetic noise absorption sheet, however, the through-holes need to be filled with the heat transfer material, which makes the production complicated. In addition, because most heat is transferred by the heat transfer material in the electromagnetic noise absorption layer, the thermal conductivity of the entire electromagnetic noise absorption layer may not be sufficient.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to the first embodiment.

FIG. 2 is an exemplary perspective view of the cooling system of the portable computer illustrated in FIG. 1.

FIG. 3 is an exemplary cross-sectional view of the first and second heat transfer sheets of the cooling system in FIG. 2.

FIG. 4 is an exemplary cross-sectional view of the thermal connection structure of the cooling system in FIG. 2.

FIG. 5 is an exemplary top view of the first and second heat transfer sheets of the thermal connection structure in FIG. 4.

FIG. 6 is an exemplary cross-sectional view of a cooling system of a portable computer according to the second embodiment.

FIG. 7 is an exemplary cross-sectional view of a cooling system of a portable computer according to the third embodiment.

FIG. 8 is an exemplary cross-sectional view of a cooling system of a portable computer according to the fourth embodiment.

FIG. 9 is an exemplary cross-sectional view of a cooling system of a portable computer according to the fifth embodiment.

FIG. 10 is an exemplary cross-sectional view of a cooling system of a portable computer according to the sixth embodiment.

FIG. 11 is an exemplary top view of the first and second heat transfer sheets of a portable computer according to the seventh embodiment.

FIG. 12 is an exemplary cross-sectional view of the cooling system of the portable computer illustrated in FIG. 11.

FIG. 13 is an exemplary cross-sectional view of a cooling system of a portable computer according to the eighth embodiment.

FIG. 14 is an exemplary cross-sectional view of a cooling system of a portable computer according to the ninth embodiment.

FIG. 15 is an exemplary cross-sectional view of a cooling system of a portable computer according to the tenth embodiment.

FIG. 16 is an exemplary cross-sectional view of a cooling system of a portable computer according to the eleventh embodiment.

FIG. 17 is an exemplary cross-sectional view of a cooling system of a portable computer according to the twelfth embodiment.

### DETAILED DESCRIPTION

Various embodiments according to the invention will be described hereinafter with reference to the accompanying drawings. In general, according to one embodiment of the invention, an electronic device comprises a circuit component, a heat sink configured to dissipate heat generated by the circuit component to the outside, and a first heat transfer sheet and a second heat transfer sheet that are arranged adjacent to each other between the circuit component and the heat sink and have thermal conductivity for thermally connecting the circuit component to the heat sink. The second heat transfer sheet has a rigidity greater than that of the first heat transfer sheet and is provided with through-holes. The first heat transfer sheet has a thermal conductivity and an elasticity greater than those of the second heat transfer sheet, and is pushed into the through-holes to thermally connect the circuit component to the heat sink.

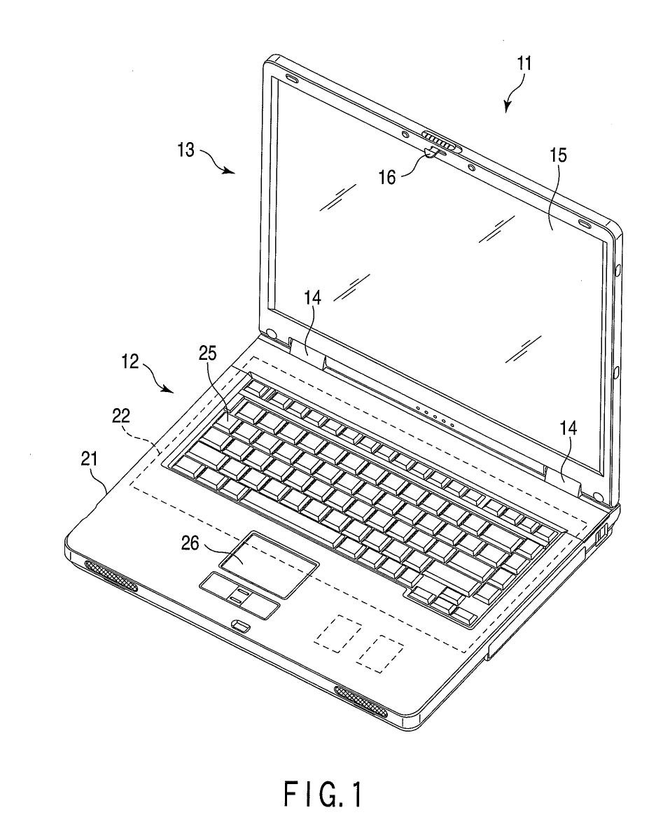

An electronic device according to the first embodiment will be explained below with reference to FIGS. 1 to 5. As illustrated in FIG. 1, a portable computer 11, which is an example of the electronic device, comprises a main unit 12, a display unit 13, and a hinge unit 14 provided between the main unit 12 and the display unit 13. The hinge unit 14 supports the display unit 13 and connects the display unit 13 rotatably to the main unit 12. The display unit 13 includes a display 15 and a latch 16.

The main unit 12 comprises a housing 21 formed of a synthetic resin, a printed circuit board 22 housed in the housing 21, a cooling system 24 for cooling a circuit component 23 on the printed circuit board 22, a keyboard 25 and a touch pad 26 mounted on the housing 21. The printed circuit board 22 includes a printed wiring board 31 and a circuit component 23 on the printed wiring board 31. The circuit component 23 is formed of, for example, a central processing unit (CPU), but is not limited thereto. The circuit component 23 may be a north bridge, a graphic chip, or any other circuit component.

The cooling system 24 comprises a thermal connection structure 32 configured to achieve a thermal connection to the circuit component 23, a fixing mechanism 33 configured to fix the thermal connection structure 32 onto the circuit component 23, a heat pipe 34 having one end connected to the thermal connection structure 32, a second heat sink 35 fixed to the other end of the heat pipe 34, and a fan unit 36 provided in the vicinity of the second heat sink 35. The heat pipe 34 may be a flat hollow cylinder which is filled and sealed with a working fluid such as alcohol.

The fixing mechanism 33 fixes a first heat sink 47 onto the circuit component 23 in such a manner that the first heat sink 47 is pressed against the circuit component 23. The fixing mechanism 33 includes the printed wiring board 31 to which the circuit component 23 is fixed, a pair of studs 37 secured onto the printed wiring board 31 by soldering, a leaf spring 38 extending between the pair of studs 37, and a screw 39 for fastening the leaf spring 38 to the studs 37. Each of the studs 37 is formed into a cylinder. The leaf spring 38 is fastened to the printed wiring board 31 in such a manner the circuit component 23 and the first heat sink 47 are sandwiched between the printed wiring board 31 and the leaf spring 38. The fixing mechanism 33 further includes a retaining plate 40 on top of the thermal connection structure 32 and the heat pipe 34.

The thermal connection structure 32 includes a first heat transfer sheet 43 arranged in direct contact with the circuit component 23, a second heat transfer sheet 44 arranged in contact with the first heat transfer sheet 43, and the first heat sink 47 arranged in contact with the second heat transfer sheet 44. The first heat sink 47 is formed of, for example, an aluminum plate, but the configuration is not limited thereto. The first heat sink 47 may be provided with multiple heat dissipating fins that protrude from the plate portion. The first heat sink 47 dissipates heat generated from the circuit component 23 into the surroundings.

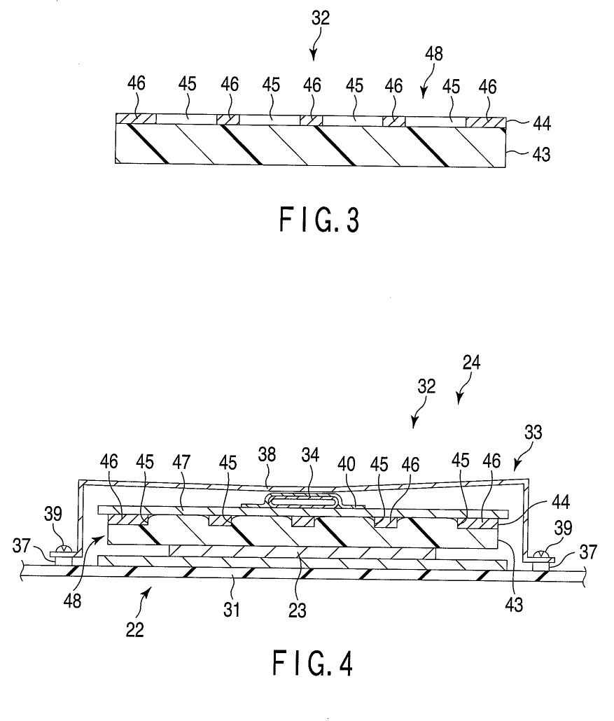

FIG. 3 shows an adhesion sheet 48 formed by attaching the first heat transfer sheet 43 and the second heat transfer sheet 44 to each other. When the fixing mechanism 33 does not apply any pressure to the adhesion sheet 48, the first heat transfer sheet 43 is not present inside the through-hole 45 of the second heat transfer sheet 44.

The first heat transfer sheet 43 is formed of a resin such as a silicon sheet, in which a filler of a high thermal conductivity is mixed. The filler, although it is not shown, contains ceramic grains, for example, and is present in uniform density in the first heat transfer sheet 43. The first heat transfer sheet 43 has a rubber-like elasticity. The thickness of the first heat transfer sheet 43 is, for example, 0.2 mm or smaller. The first heat transfer sheet 43 has a thermal conductivity and elasticity greater than those of the second heat transfer sheet 44.

The second heat transfer sheet 44 is formed of a foil of a metal such as copper and aluminum or a carbon plate. The thickness of the second heat transfer sheet 44 is, for example, 0.05 mm or smaller. The second heat transfer sheet 44 has a thermal conductivity of, for example, 140 W/m·K or higher. The second heat transfer sheet 44 has a rigidity greater than that of the first heat transfer sheet 43.

As illustrated in FIG. 5, the second heat transfer sheet 44 has a plurality of through-holes 45 and a frame unit 46 defining the circumferences of the through-holes 45. The second heat transfer sheet 44 is a 15 mm-by-15 mm square, for example. Each of the through-holes 45 is hexagonal and has a diameter of 2.5 to 3.5 mm, for example. The frame unit 46 is formed into a hexagonal lattice. Each of the through-holes 45 is arranged inside each frame of the frame unit 46, forming a honeycomb structure altogether. The shape of a through-hole 45 is not limited to a hexagon, but may be a circle. In addition, the arrangement of the through-holes 45 is not limited to the honeycomb structure. The frame unit 46 may be formed into a grid so that the through-holes 45 can be arranged inside individual squares of the grid of the frame unit 46.

As illustrated in FIG. 4, when the fixing mechanism 33 applies a pressure to the first heat transfer sheet 43, the sheet 43 is pushed into the through-holes 45 so as to thermally connect the circuit component 23 to the first heat sink 47.

The first heat transfer sheet 43 and the second heat transfer sheet 44 are adhered to each other into a single adhesion sheet 48 in advance. The adhesion sheet 48 is prepared by individually rolling the first heat transfer sheet 43 and the second heat transfer sheet 44 and attaching the sheets to further apply a pressure for a certain period of time. The press work creates the through-holes 45 in the second heat transfer sheet 44. The thermal connection is attained between the circuit component 23 and the first heat sink 47 by arranging this sheet therebetween.

The resin material of the first heat transfer sheet 43 itself has a viscosity, and thus after the pressuring, no additional adhesive is required to adhere the first heat transfer sheet 43 to the second heat transfer sheet 44. Furthermore, according to the present embodiment, the first heat transfer sheet 43 and the second heat transfer sheet 44 are adopted for the thermal connection, which is different in structure from a thermal connection utilizing grease. Hence, the present embodiment is free from “pump-out”, or squeezed-out grease under the pressure.

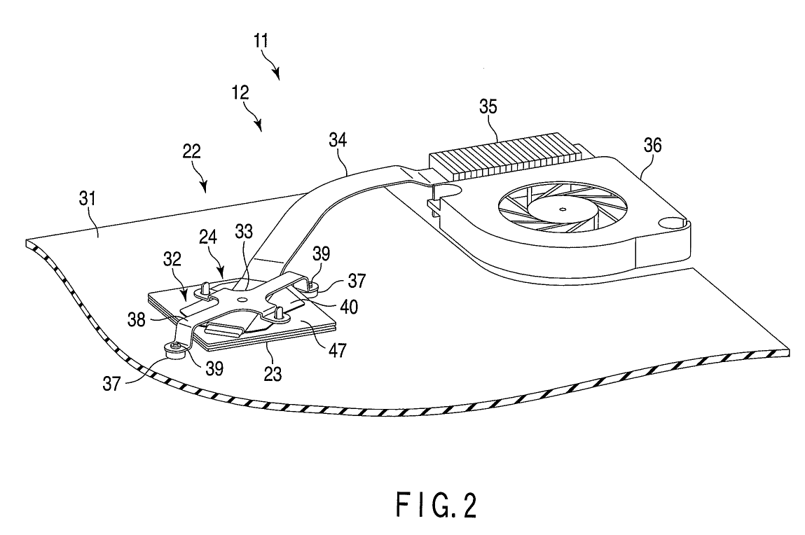

The operation of the thermal connection structure 32 according to the present embodiment will be explained with reference to FIGS. 2 and 4. The heat generated by the circuit component 23 is transferred mainly via the first heat transfer sheet 43 to the first heat sink 47. In this heat transfer, the second heat transfer sheet 44 functions in an auxiliary manner, helping the transfer from the circuit component 23 to the first heat sink 47. Some of the heat transferred to the first heat sink 47 is dissipated directly to the ambient air. Most of the heat transferred to the first heat sink 47 is transferred via the heat pipe 34 to the second heat sink 35. The heat collected in the second heat sink 35 is conveyed to the air sent by the fan unit 36. The heated air is released to the outside of the housing 21, thereby dissipating the heat to the ambient air.

The electronic device according to the first embodiment comprises the circuit component 23, the heat sink for dissipating the heat generated by the circuit component 23 to the ambient air, the first heat transfer sheet 43 and the second heat transfer sheet 44 that are arranged adjacent to each other between the circuit component 23 and the heat sink and have thermal conductivity so as to thermally connect the circuit component 23 to the heat sink. The second heat transfer sheet 44 has a rigidity greater than that of the first heat transfer sheet 43, and is provided with the through-holes 45. The first heat transfer sheet 43 has a thermal conductivity and elasticity greater than those of the second heat transfer sheet 44 so that it is pushed into the through-holes 45 to thermally connect the circuit component 23 to the first heat sink 47.

With such a structure, in which the first heat transfer sheet 43 with a high thermal conductivity thermally connects the circuit component 23 to the first heat sink 47, the efficiency of dissipating heat from the circuit component 23 can be improved. Even if a minute foreign substance is present between the second heat transfer sheet 44 and the circuit component 23, the first heat transfer sheet 43 pushed into the through-holes 45 can absorb the substance. This prevents the efficiency of cooling the circuit component 23 from suddenly dropping by the contamination. Further, because the second heat transfer sheet 44 also has a thermal conductivity, the heat can be transferred by way of the second heat transfer sheet 44 from the circuit component 23 to the first heat sink 47. In addition, because the first heat transfer sheet 43 goes into the through-holes 45 of the second heat transfer sheet 44, no thermally conductive material is required to independently put into the through-holes 45, and thus a thermal connection can be readily formed.

The electronic device further includes the fixing mechanism 33 to fix the circuit component 23 and the heat sink to each other in such a manner that the first heat sink 47 is pressed against the circuit component 23. Due to such a structure, pressure can be applied onto the first heat transfer sheet 43 and the second heat transfer sheet 44 that are arranged between the circuit component 23 and the first heat sink 47. In this manner, the first heat transfer sheet 43 can be easily pushed into the through-holes 45 of the second heat transfer sheet 44.

The first heat transfer sheet 43 and the second heat transfer sheet 44 are adhered to each other in advance. In this structure, because the rigid second heat transfer sheet 44 is adhered to the elastic first heat transfer sheet 43, the resultant adhesion sheet 48 is given a mechanical strength in comparison with a structure incorporating the first heat transfer sheet only. This enhances the workability when handling the adhesion sheet 48.

Multiple through-holes 45 are provided in a honeycomb structure in the second heat transfer sheet 44. Such a structure increases the area of the through-holes 45 in the second heat transfer sheet 44. This means that the area of the portion thermally connected to the first heat transfer sheet 43 is increased, and that the heat can be effectively dissipated from the circuit component 23. Furthermore, although a large area is allocated to the through-holes 45 in this structure, it does not significantly reduce the strength of the second heat transfer sheet 44, and the operability of the adhesion sheet 48 in which the first heat transfer sheet 43 and the second heat transfer sheet 44 are adhered to each other can be maintained.

The fixing mechanism 33 includes the printed wiring board 31 to which the circuit component 23 is fixed, and the leaf spring 38 fixed to the printed wiring board 31 to sandwich the circuit component 23 and the first heat sink 47 together with the printed wiring board 31. Thus, the fixing mechanism 33 for pressing the first heat sink 47 against the circuit component 23 can be realized with a simple structure.

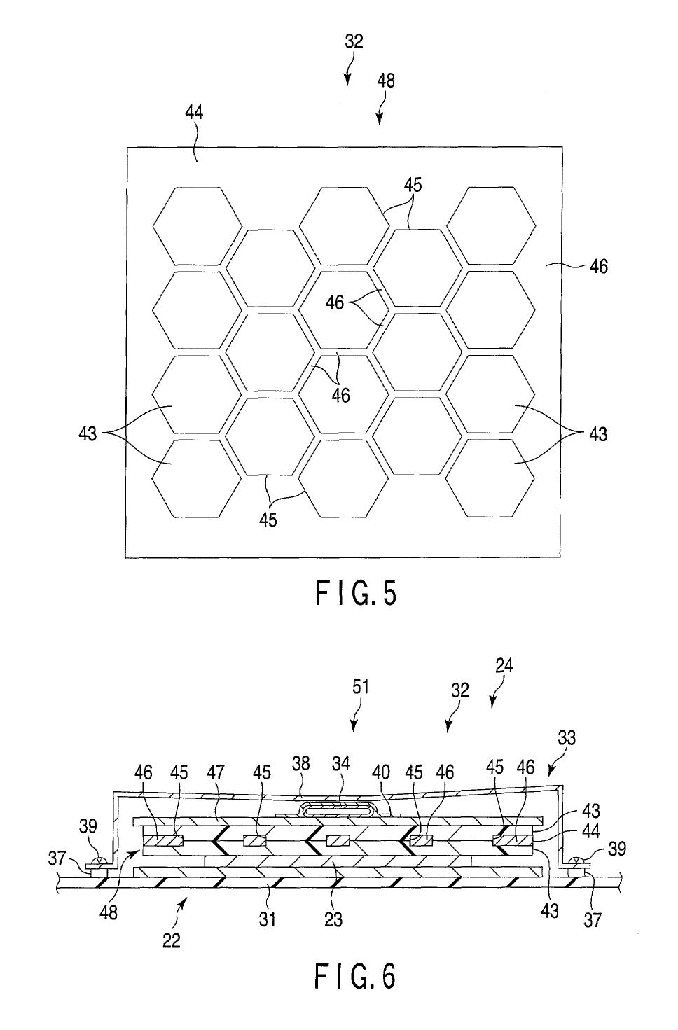

Next, an electronic device according to the second embodiment will be explained with reference to FIG. 6. A portable computer 51 is an example of the electronic device according to the second embodiment. The structure is different from the first embodiment in that the first heat transfer sheet 43 includes two sheets, but the rest of the structure is the same as the first embodiment. Thus, the explanation of the second embodiment focuses on the different portion. As for the common portion, the same reference numbers are given, and the explanation thereof is omitted.

As illustrated in FIG. 6, the structure according to the second embodiment includes a pair of first heat transfer sheets 43. The second heat transfer sheet 44 is arranged between the first heat transfer sheets 43. When pressure is applied to the first heat transfer sheets 43 and the second heat transfer sheet 44 between the circuit component 23 and the first heat sink 47, the first heat transfer sheets 43 is pushed into the through-holes 45 of the second heat transfer sheet 44.

According to the second embodiment, the second heat transfer sheet 44 is sandwiched between a pair of first heat transfer sheets 43. Due to such a structure, the first heat transfer sheets 43 that have a high elasticity are arranged on the two sides of the second heat transfer sheet 44, which offers a thermal connection resistant to admixture of foreign substances. In addition, the second heat transfer sheet 44 gives a mechanical strength to the adhesion sheet 48 formed by adhering the first heat transfer sheets 43 to the second heat transfer sheet 44, which improves the handleability of the adhesion sheet 48.

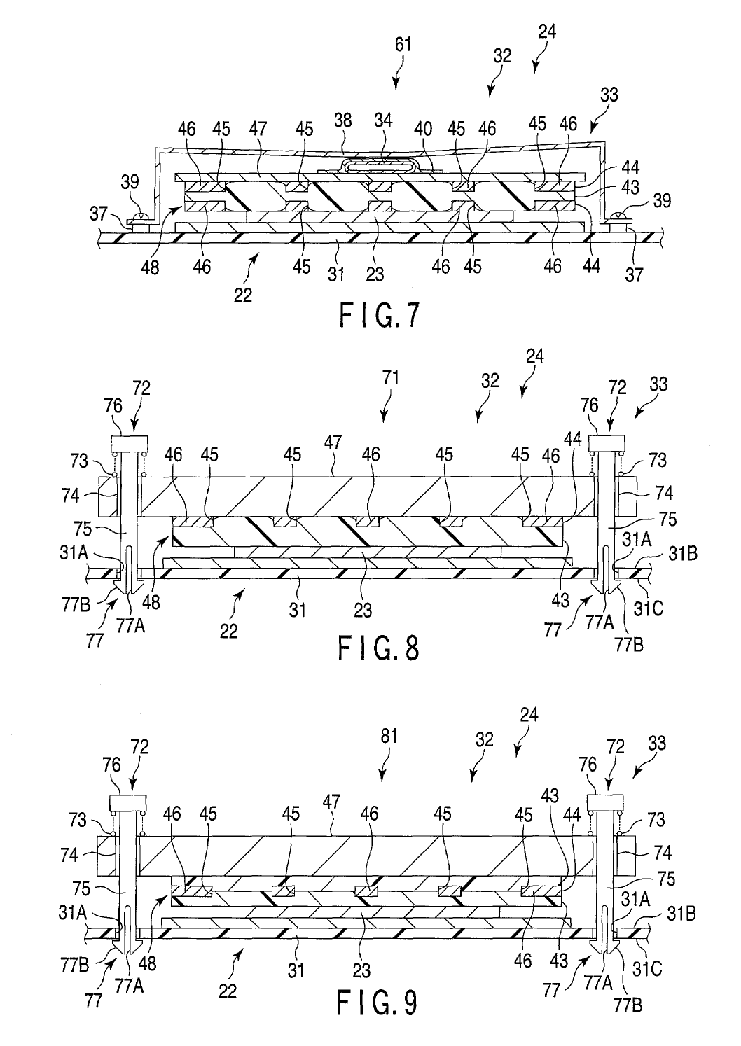

An electronic device according to the third embodiment will be explained with reference to FIG. 7. A portable computer 61 is an example of the electronic device according to the third embodiment. The structure is different from the first embodiment in that the second heat transfer sheet 44 is formed of two sheets. The rest of the structure is the same as the first embodiment, and therefore the explanation focuses on the difference. The components of the common portion are given the same reference numbers, and the explanation thereof is omitted.

The structure according to the third embodiment includes a pair of second heat transfer sheets 44. The first heat transfer sheet 43 is arranged between the second heat transfer sheets 44. When the first heat transfer sheet 43 and the second heat transfer sheets 44 are pressed between the circuit component 23 and the first heat sink 47, the first heat transfer sheet 43 is pushed into the through-holes 45 formed in each of the two second heat transfer sheets 44. The circuit component 23 and the first heat sink 47 are thermally connected to each other by the first heat transfer sheet 43 in the through-holes 45. In addition, the circuit component 23 and the first heat sink 47 are also thermally connected by way of the second heat transfer sheet 44. According to this embodiment, the two second heat transfer sheets 44 are prepared with the same material as in the first embodiment. However, one of the second heat transfer sheets 44 may be formed of an elastic material having a different composition.

According to the third embodiment, the first heat transfer sheet 43 is sandwiched between the second heat transfer sheets 44. In this structure, the two second heat transfer sheets 44 having a high rigidity are provided around the first heat transfer sheet 43 having a high elasticity. The workability of the first heat transfer sheet 43 and the second heat transfer sheets 44 is thereby improved, which facilitates the assembly of the portable computer 61.

An electronic device according to the fourth embodiment will be explained with reference to FIG. 8. A portable computer 71 is an example of the electronic device according to the fourth embodiment. This embodiment is different from the first embodiment in the structures of the fixing mechanism 33 and the first heat sink 47, but the rest is the same as the first embodiment. Thus, the explanation focuses on the different portion. The common components are given the same reference numbers, and the explanation thereof is omitted.

As illustrated in FIG. 8, the fixing mechanism 33 includes the printed wiring board 31 having engagement holes 31A, pins 72 inserted in the engagement holes 31A of the printed wiring board 31, and compression springs 73 arranged between the pins 72 and the first heat sink 47. The first heat sink 47 is provided with fixing holes 74 in its four corner portions, for example. The pins 72 are inserted through the fixing holes 74.

The printed wiring board 31 has a first surface 31B on which the circuit component 23 is attached, a second surface 31C which is opposite to the first surface 31B, and the engagement holes 31A running between the first surface 31B and the second surface 31C. Each of the pins 72 has a shank 75 inserted into a fixing hole 74 of the first heat sink 47 and an engagement hole 31A of the printed wiring board 31, a head 76 provided on one end of the shank 75, and a hook 77 provided on the other end of the shank 75.

The hook 77 has a groove portion 77A formed in the center thereof and a hooked portion 77B formed on the two sides of the groove portion 77A. The hook 77 is engaged in the second surface 31C of the printed wiring board 31 at the hooked portion 77B. The heat pipe 34, the second heat sink 35 and the fan unit 36 according to the present embodiment are not shown in the drawing. The compression spring 73 is arranged around the shank 75 between the head 76 and the first heat sink 47 in a compressed manner.

According the fourth embodiment, the first heat sink 47 has the fixing holes 74 in its corners. The fixing mechanism 33 has the printed wiring board 31 which includes the first surface 31B onto which the circuit component 23 is fixed, the second surface 31C on the opposite side to the first surface 31B, and the engagement holes 31A running between the first surface 31B and the second surface 31C; the pins 72 each of which includes the shank 75 that is inserted into one of the fixing holes 74 and one of the engagement holes 31A, the head 76 provided on one end of the shank 75, and the hook 77 provided on the other end of the shank 75 to be engaged in the second surface 31C; and the compression springs 73 arranged around each of the shanks 75 between the head 76 and the first heat sink 47 in a compressed manner.

In such a structure, the hook 77 of each pin 72 is hooked onto the second surface 31C of the printed wiring board 31, and the first heat sink 47 is thereby pressed against the circuit component 23 by way of the compression spring 73. Thus, the first heat sink 47 is pressed against the printed circuit board 22 with a single operation, improving the assembly workability of the portable computer 71.

An electronic device according to the fifth embodiment will be explained with reference to FIG. 9. A portable computer 81 is an example of the electronic device according to the fifth embodiment. The portable computer 81 is different from the fourth embodiment in inclusion of two first heat transfer sheets 43. The rest of the structure is the same as the fourth embodiment, and thus the explanation focuses on the difference. The common components are given the same reference numbers, and the explanation thereof is omitted.

The structure according to the fifth embodiment first comprises a pair of first heat transfer sheets 43. The second heat transfer sheet 44 is arranged between the first heat transfer sheets 43. When the first heat transfer sheets 43 and the second heat transfer sheet 44 are compressed between the circuit component 23 and the first heat sink 47, the first heat transfer sheets 43 are pushed into the through-holes 45 of the second heat transfer sheet 44.

According the fifth embodiment, the first heat transfer sheets 43 having a high elasticity are arranged on the two sides of the second heat transfer sheet 44, offering a thermal connection resistant to the admixture of any foreign substance.

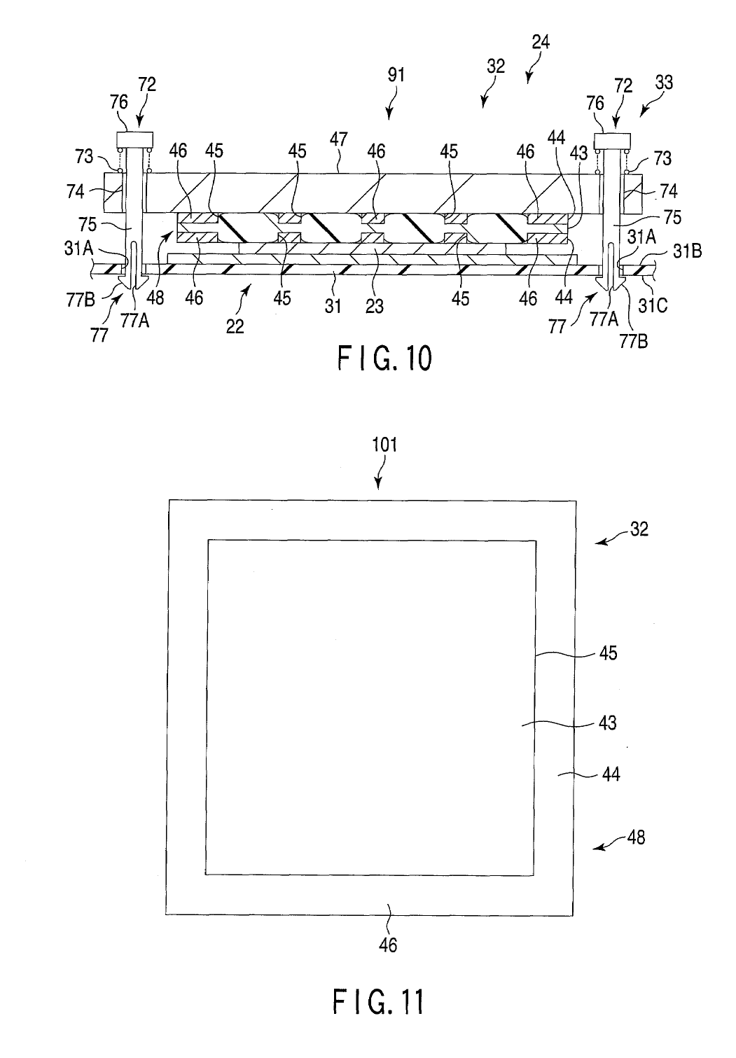

An electronic device according to the sixth embodiment will be explained with reference to FIG. 10. A portable computer 91 is an example of the electronic device according to the sixth embodiment. The portable computer 91 is different from the fourth embodiment in inclusion of two second heat transfer sheets 44, but the rest of the structure is the same as the fourth embodiment. Thus, the explanation focuses on the difference, and the explanation of the common components is omitted by providing them with the same reference numbers.

As illustrated in FIG. 10, the structure according to the sixth embodiment comprises a pair of second heat transfer sheets 44. The first heat transfer sheet 43 is arranged between the second heat transfer sheets 44. In the structure where the first heat transfer sheet 43 and the second heat transfer sheets 44 are sandwiched and pressed between the circuit component 23 and the first heat sink 47, the first heat transfer sheet 43 is pushed into the through-holes 45 of each of the two second heat transfer sheets 44. The circuit component 23 and the first heat sink 47 are thermally connected to each other by way of the first heat transfer sheet 43 inside the through-holes 45.

According to the sixth embodiment, the first heat transfer sheet 43 is sandwiched between a pair of second heat transfer sheets 44. In this structure, the two second heat transfer sheets 44 having a high rigidity are arranged around the first heat transfer sheet 43 having a high elasticity. The rigidity of the second heat transfer sheets 44 helps the workability of the first heat transfer sheet 43 and the second heat transfer sheet 44 increase, and facilitates the assembly of the portable computer 91.

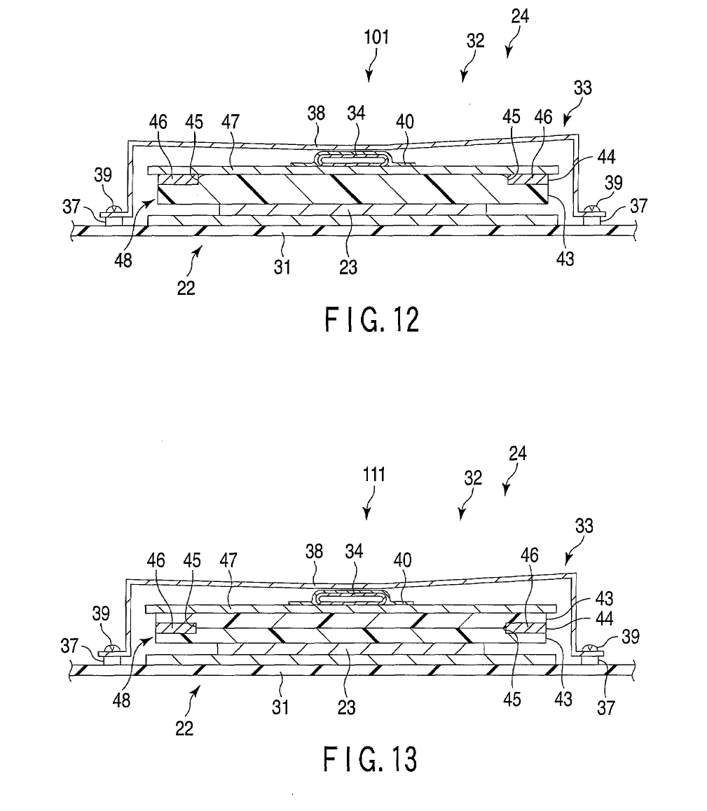

An electronic device according to the seventh embodiment will be explained with reference to FIGS. 11 and 12. A portable computer 101 is an example of the electronic device according to the seventh embodiment. The structure of the through-holes 45 of the second heat transfer sheet 44 is different from that of the first embodiment, but the rest of the structure is the same as the first embodiment. Thus, the explanation is focused on the difference. The common components are given the same reference numbers, and the explanation of the common components is omitted.

As illustrated in FIG. 11, the second heat transfer sheet 44 is provided with a square through-hole 45 in its center. In other words, the second heat transfer sheet 44 is shaped into a frame, having a frame unit 46 that defines the circumference of the through-holes 45.

As illustrated in FIG. 12, the first heat transfer sheet 43 and the second heat transfer sheet 44 are sandwiched and pressed between the circuit component 23 and the first heat sink 47. Then, the first heat transfer sheet 43 is pushed into the through-hole 45 of the second heat transfer sheet 44. The shape of the through-hole 45 is not limited to a square, but it may be a circle or any polygon other than a quadrangle.

The structure according to the seventh embodiment includes a single through-hole 45, where the second heat transfer sheet 44 is shaped into a frame defining the through-hole 45. In this structure, the first heat transfer sheet 43 is given a large area in contact with the circuit component 23 and the first heat sink 47. In addition, because the second heat transfer sheet 44 having a high rigidity is formed into a frame, the adhesion sheet 48 formed by adhering the first heat transfer sheet 43 and the second heat transfer sheet 44 to each other is given a mechanical strength, offering excellent handleability.

Next, an electronic device according to the eighth embodiment will be explained with reference to FIG. 13. A portable computer 111 is an example of the electronic device according to the eighth embodiment. The eighth embodiment is different from the seventh embodiment in incorporation of two first heat transfer sheets 43, but the rest of the structure is the same as the seventh embodiment. The explanation is therefore focused on the difference, while the common components are given the same reference numbers and the explanation thereof is omitted.

The structure according to the eighth embodiment includes a pair of first heat transfer sheets 43, and the second heat transfer sheet 44 is arranged between the first heat transfer sheets 43. The first heat transfer sheets 43 and the second heat transfer sheet 44 are sandwiched and pressed between the circuit component 23 and the first heat sink 47, which pushes the first heat transfer sheets 43 into the through-hole 45 of the second heat transfer sheet 44.

According to the eighth embodiment, the first heat transfer sheets 43 having a large elasticity are positioned on the two sides of the second heat transfer sheet 44. This offers a thermal connection resistant to admixture of foreign substances. Furthermore, owing to the second heat transfer sheet 44, the adhesion sheet 48 formed by adhering the first heat transfer sheets 43 and the second heat transfer sheet 44 to each other is given a mechanical strength, which improves the handleability.

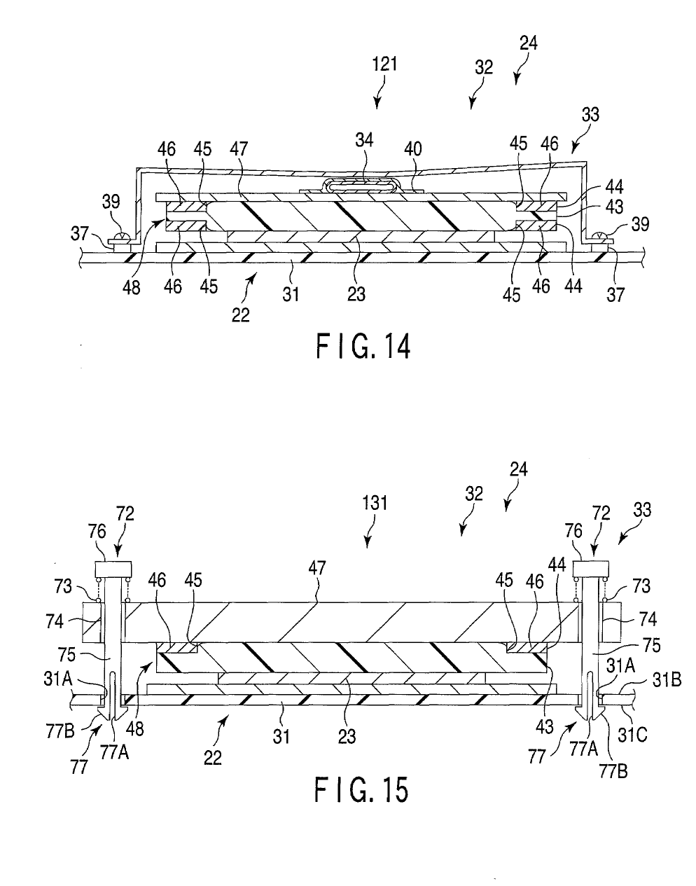

An electronic device according to the ninth embodiment will be explained with reference to FIG. 14. A portable computer 121 is an example of the electronic device according to the ninth embodiment. The ninth embodiment is different from the seventh embodiment in inclusion of two second heat transfer sheets 44, but the rest of the structure is the same as the seventh embodiment. The explanation is therefore focused on the difference, while the common components are given the same reference numbers and the explanation thereof is omitted.

The ninth embodiment includes a pair of second heat transfer sheets 44. The first heat transfer sheet 43 is arranged between the second heat transfer sheets 44. The first heat transfer sheet 43 and the second heat transfer sheets 44 are sandwiched and pressed between the circuit component 23 and the first heat sink 47, pushing the first heat transfer sheet 43 into through-hole 45 of each of the two second heat transfer sheets 44. As a result, the circuit component 23 and the first heat sink 47 are thermally connected to each other by way of the first heat transfer sheet 43 inside the through-holes 45.

According to the ninth embodiment, the two second heat transfer sheets 44 are positioned around the first heat transfer sheet 43 having a high elasticity. This improves the handleability of the adhesion sheet 48 in which the first heat transfer sheet 43 and the second heat transfer sheets 44 are adhered to each other. As a result, an excellent assembly workability of the portable computer 121 can be offered.

An electronic device according to the tenth embodiment will be explained with reference to FIG. 15. A portable computer 131 is an example of the electronic device according to the tenth embodiment. The structures of the fixing mechanism 33 and the first heat sink 47 are different from those of the seventh embodiment in FIG. 12. The rest of the device structure is the same as the seventh embodiment. Thus, the explanation is focused on the difference, while the common components are given the same reference numbers and the explanation thereof is omitted.

As shown in FIG. 15, the structures of the fixing mechanism 33 and the first heat sink 47 are the same as those of the fourth embodiment in FIG. 8. The hook 77 of each pin 72 is engaged in the second surface 31C of the printed wiring board 31 at its hooked portion 77B.

According to the tenth embodiment, the hook 77 of the pin 72 is hooked onto the second surface 31C of the printed wiring board 31 so that the first heat sink 47 can be pressed against the circuit component 23 with the tension of the compression spring 73. Hence, the first heat sink 47 can be pressed against the printed circuit board 22 with a single operation, which improves the assemble workability of the portable computer 131.

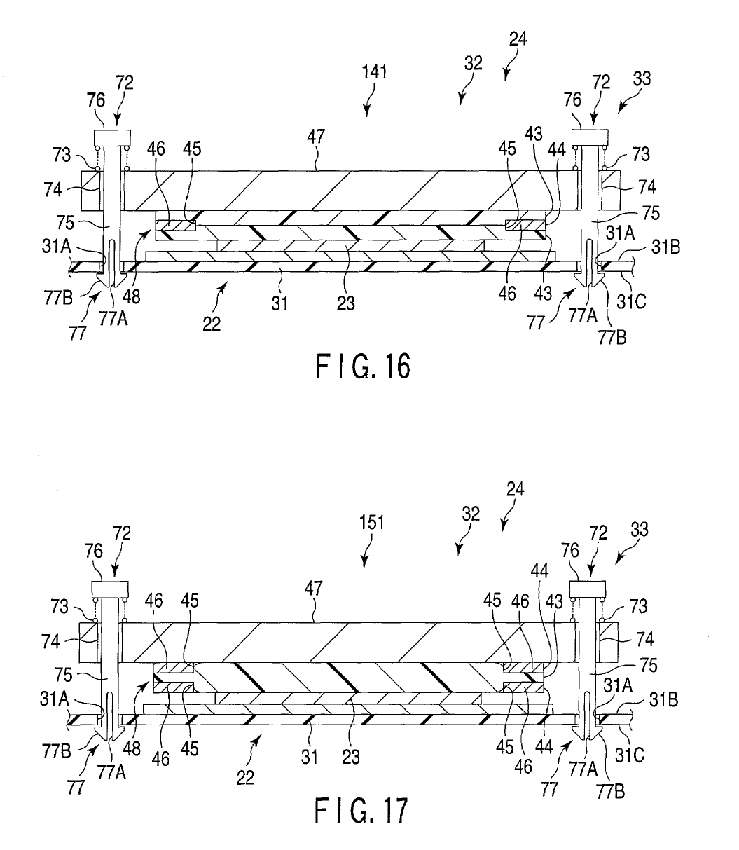

An electronic device according to the eleventh embodiment will be explained with reference to FIG. 16. A portable computer 141 is an example of the electronic device according to the eleventh embodiment. The eleventh embodiment is different from the tenth embodiment in inclusion of two first heat transfer sheets 43, but the rest of the structure is the same as the tenth embodiment. Thus, the explanation is focused on the difference. The common components are given the same reference numbers, and the explanation thereof is omitted.

The eleventh embodiment includes a pair of first heat transfer sheets 43, where the second heat transfer sheet 44 is arranged between the first heat transfer sheets 43. The first heat transfer sheets 43 and the second heat transfer sheet 44 are sandwiched and pressed between the circuit component 23 and the first heat sink 47, and the first heat transfer sheets 43 are thereby pushed into the through-hole 45 of the second heat transfer sheet 44.

According to the eleventh embodiment, the first heat transfer sheets 43 having a high elasticity are positioned on the two sides of the second heat transfer sheet 44. This offers a thermal connection resistant to admixture of foreign substances. In addition, because the second heat transfer sheet 44 having a high rigidity gives the adhesion sheet 48 formed by attaching the first heat transfer sheets 43 and the second heat transfer sheet 44 to each other a mechanical strength, handleability of the adhesion sheet 48 is improved.

An electronic device according to the twelfth embodiment will be explained with reference to FIG. 17. A portable computer 151 is an example of the electronic device according to the twelfth embodiment. The twelfth embodiment is different from the tenth embodiment in inclusion of two second heat transfer sheets 44, but the rest of the structure is the same as the tenth embodiment. Thus, the explanation is focused on the difference, while the common components are given the same reference numbers and the explanation thereof is omitted.

The twelfth embodiment includes a pair of second heat transfer sheets 44. The first heat transfer sheet 43 is provided between the second heat transfer sheets 44. The first heat transfer sheet 43 and the second heat transfer sheets 44 are sandwiched and pressed between the circuit component 23 and the first heat sink 47, and the first heat transfer sheet 43 is pushed into the through-hole 45 of each of the second heat transfer sheets 44. The circuit component 23 and the first heat sink 47 are thermally connected to each other by way of the first heat transfer sheet 43 inside the through-holes 45.

According to the twelfth embodiment, a pair of second heat transfer sheets 44 having a high rigidity are provided around the first heat transfer sheet 43 having a high elasticity. This improves the handleability of the adhesion sheet 48 formed by attaching the first heat transfer sheet 43 and the second heat transfer sheets 44 to each other, thereby enhancing the assembly workability of the portable computer 151.

The electronic device of the present invention is not limited to a portable computer. The present invention may be applied to any other electronic device such as a personal digital assistant. The electronic device may be modified in various manners without departing from the scope of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
an electronic circuit;
a heat sink configured to dissipate heat generated by the circuit; and
a first heat transfer sheet and a second heat transfer sheet positioned adjacent to each other between the circuit and the heat sink, and configured to thermally connect the circuit and the heat sink to each other,
wherein rigidity of the second heat transfer sheet is higher than rigidity of the first heat transfer sheet, and the second heat transfer sheet comprises a through-hole; and
wherein a thermal conductivity and elasticity of the first heat transfer sheet are greater than a thermal conductivity and elasticity of the second heat transfer sheet, and the first transfer sheet is partially in the through-hole in order to thermally connect the circuit to the heat sink.

2. The electronic device of claim 1, further comprising:
a retainer configured to attach the circuit to the heat sink in such a manner that the heat sink is pressed against the circuit.

3. The electronic device of claim 2, wherein:
the first heat transfer sheet and the second heat transfer sheet are adhered to each other.

4. The electronic device of claim 3, wherein:
a plurality of through-holes are provided in a honeycomb structure in the second heat transfer sheet.

5. The electronic device of claim 4, wherein the retainer comprises:
a printed wiring board configured to mount the circuit fixed; and
a leaf spring fixed on the printed wiring board in such a manner that the circuit and the heat sink are between the leaf spring and the printed wiring board.

6. The electronic device of claim 5, wherein:
the second heat transfer sheet is between a pair of first heat transfer sheets.

7. The electronic device of claim 5, wherein:
the first heat transfer sheet is between a pair of second heat transfer sheets.

8. The electronic device of claim 4, wherein:
the heat sink has a fixing hole in a corner of the heat sink; and
the retainer comprises:
a printed wiring board comprising a first surface configured to mount the circuit fixed, a second surface on an opposite side to the first surface, and an engagement hole between the first surface and the second surface;
a pin comprising a shaft in the fixing hole and the engagement hole, a head on a first end of the shaft, and a hook on a second end of the shaft to be engaged with the second surface; and
a compression spring around the shaft between the head and the heat sink in a compressed manner.

9. The electronic device of claim 8, wherein:
the second heat transfer sheet is between a pair of first heat transfer sheets.

10. The electronic device of claim 8, wherein:
the first heat transfer sheet is between a pair of second heat transfer sheets.

11. The electronic device of claim 3, comprising:
a single through-hole,
wherein the second heat transfer sheet is shaped into a frame defining a circumference of the through-hole.

12. The electronic device of claim 11, wherein:
the retainer comprises:
a printed wiring board configured to mount the circuit fixed; and
a leaf spring fixed onto the printed wiring board in such a manner that the circuit and the heat sink are between the leaf spring and the printed wiring board.

13. The electronic device of claim 12, wherein:
the second heat transfer sheet is between a pair of first heat transfer sheets.

14. The electronic device of claim 12, wherein:
the first heat transfer sheet is between a pair of second heat transfer sheets.

15. The electronic device of claim 11, wherein:
the heat sink comprises a fixing hole in a corner of the heat sink; and
the retainer comprises:
a printed wiring board comprising a first surface configured to mount the circuit fixed, a second surface on an opposite side to the first surface, and an engagement hole between the first surface and the second surface;
a pin comprising a shaft in the fixing hole and the engagement hole, a head on a first end of the shaft, and a hook on a second end of the shaft to be engaged in the second surface; and
a compression spring around the shaft between the head and the heat sink in a compressed manner.

16. The electronic device of claim 15, wherein:
the second heat transfer sheet is between a pair of first heat transfer sheets.

17. The electronic device of claim 15, wherein:
the first heat transfer sheet is between a pair of second heat transfer sheets.
